(19) United States
(12) Patent Application Publication
(10) Pub. No.: US 2014/0293542 A1
(43) Pub. Date: Oct. 2, 2014

(54) Thermal mgmt. device for high-heat flux electronics

(71) Applicant: Jan Vetrovec, Larkspur, CO (US)

(72) Inventor: Jan Vetrovec, Larkspur, CO (US)

(21) Appl. No.: 13/986,084

(22) Filed: Mar. 30, 2013

(51) Int. Cl. H01L 23/473

(52) U.S. Cl. CPC H01L 23/473
USPC 361/699; 165/104.31

(57) ABSTRACT

The invention is for an apparatus and method for removal of waste heat at high-flux from electronic, photonic, and other components. The apparatus of the present invention is a self-contained unit comprising a closed flow loop flowing liquid metal coolant pumped by an integral magneto-hydrodynamic (MHD) pump. Liquid metal coolant flow is arranged to impinge onto a thin member mounting a heat load. Impinging flow of liquid metal coolant offers a high heat transfer coefficient, which translates to comparably low thermal resistance between the heat load and the liquid metal coolant. As a result, the apparatus may remove heat from the heat load at very high flux. Waste heat acquired from the heat load may be transferred at reduced flux into a flowing secondary coolant, heat pipe, structure, or a radiation panel. Temperature of the heat load may be varied by varying the MHD pump drive current.

### CROSS-REFERENCE TO RELATED APPLICATIONS

This application claims priority from U.S. provisional patent applications U.S. Ser. No. 61/686,134, filed on Mar. 30, 2012 and entitled “Thermal Management for Solid State High-Power Electronics,” the entire contents of which are hereby expressly incorporated by reference This patent application is a continuation-in-part patent application of: U.S. Ser. No. 12/290,195 filed on Oct. 28, 2008 and entitled HEAT TRANSFER DEVICE; U.S. Ser. No. 12/584,490 filed on Sep. 5, 2009 and entitled HEAT TRANSFER DEVICE; U.S. Ser. No. 12/932,585 filed on Feb. 28, 2011 and entitled THERMAL INTERFACE DEVICE; and U.S. Ser. No. 13/385,317 filed on Feb. 13, 2012 and entitled THERMAL MANAGEMENT FOR SOLID STATE HIGH-POWER ELECTRONICS the entire contents of all of which are hereby expressly incorporated by reference.

### GOVERNMENT RIGHTS NOTICE

This invention was made with Government support under Contract No. FA9453-10-C-0061 awarded by the U.S. Air Force. The Government has certain rights in the invention.

### FIELD OF THE INVENTION

This invention relates generally to a removal of heat from a heat-generating component and more specifically to a removal of heat at high flux.

### BACKGROUND OF THE INVENTION

The subject invention is an apparatus and a method for removal of waste heat from heat-generating components including analog solid-state electronics, digital solid-state electronics, semiconductor laser diodes, light emitting diodes, photovoltaic cells, vacuum electronics, and solid-state laser crystals.

There are many devices generating waste heat as a byproduct of their normal operations. These include analog solid-state electronic components, digital solid-state electronic components, semiconductor laser diodes, light emitting diodes for solid-state lighting, solid-state laser components, laser crystals, vacuum electronic components, and photovoltaic cells. Waste heat must be efficiently removed from such components to prevent overheating and consequential loss of efficiency, malfunction, or even catastrophic failure. Methods for waste heat management may include conductive heat transfer, convective heat transfer, and radiative heat transfer, or various combinations thereof. For example, waste heat removed from heat generating components may be transferred to a heat sink by a flowing heat transfer fluid. Such a heat transfer fluid is also known as a coolant.

Meeting the cooling requirements for the new generation of heat-generating components (HGC) is very challenging for the thermal management technologies of prior art. For example, an ongoing miniaturization of semiconductor digital and analog electronic devices requires removal of heat at ever increasing fluxes now approaching the order of several hundreds of watts per square centimeter. Traditional heat sinks and heat spreaders have a large thermal resistance, which contributes to elevated junction temperatures and thus reducing device reliability. As a result, removal of heat often becomes the limiting factor and a barrier to further performance enhancements. Improved thermal management is necessary to boost heat transfer rates, eliminate hot spots, and reduce volume, while allowing for higher electric current density.

High-power electronic chips (such as transistors and diodes) may be used for construction of electronic inverters, which invert direct current (DC) into 3-phase alternating current (AC). Such inverters are critical components of some electric vehicles, hybrid electric vehicles, and solar power plants.

High-brightness light emitting diodes (LED) being developed for solid-state lighting for general illumination in commercial and household applications also require improved thermal management. These new light sources are becoming of increased importance as they offer up to 75% savings in electric power consumption over conventional lighting systems. Waste heat must be effectively removed from the LED chip to reduce junction temperature, thereby prolonging LED life and making LED cost effective over traditional lighting sources.

Another class of electronic components requiring improved cooling are semiconductor-based high-power laser diodes used for direct material processing and pumping of solid-state lasers. Generation of optical output from laser diodes is accompanied by production of large amount of waste heat that must be removed at a flux on the order of several hundreds of watts per square centimeter. In addition, the temperature of high-power laser diodes must be controlled within a narrow range to avoid undesirable shifts in output wavelength.

Photovoltaic cells (including solar electric cells and thermo-photovoltaic cells) are becoming increasingly important for generation of electricity. However, the cost per unit area of photovoltaic cells remains high. Happily, by using light concentrators, one may generate more electric power from smaller, more economical cells. For this approach to be successful, it is necessary to remove waste heat from the photovoltaic cells at increased flux. Similarly, high-performance crystals used in solid-state lasers generate waste heat that may require removal at fluxes in the neighborhood of thousand watts per square centimeter.

Anodes in x-ray tubes are subjected to very high thermal loading. Rotating anodes are frequently used to spread the heat to avoid overheating. Such rotating anodes inside a vacuum enclosure are impractical for use in a new generation of x-ray tubes for use in compact and portable devices in medical and security applications. A compact and lightweight heat transfer component having no moving parts inside the vacuum is very desirable.

Current approaches for removal of waste heat at high fluxes include 1) spreading of heat with elements having high thermal conductivity and/or 2) forced convection cooling using liquid coolants. However, even with heat spreading materials having extremely high thermal conductivity such as diamond films and certain graphite fibers, a significant thermal gradient is required to rapidly conduct large amounts of heat even over short distances. In addition, passive heat spreaders are not conducive to temperature control of the HGC. Forced convection methods for removal of waste heat at high fluxes may use microchannel heat exchangers or impingement jets. Literature indicates that conventional coolants such as water, alcohol, ethylene glycol, or fluorocarbons (e.g., Freon®) have a thermal conductivity less than 1 watt per meter-degree Kelvin. To obtain a desirably high heat transfer coefficient with conventional coolants may require flowing such coolants at very high velocity. However, this results in undesirably high coolant consumption and it requires a large pumping system. The latter is complex, costly to construct, and it requires significant amount of power to operate. High flow velocities also cause deleterious flow-induced vibrations, which are extremely undesirable in many precision systems, such as optical systems and lasers, especially on vibration-sensitive platforms such as spacecraft.

Metals have a thermal conductivity several orders-of-magnitude greater than water and organic liquids. Liquid (molten) metals have a viscosity comparable to that of water. As a result, liquid metals are excellent candidates for advantageous cooling in many demanding applications, especially where heat must be removed at high heat flux. Initially, cooling by liquid metal (i.e., liquid metal cooling) was developed for thermal management of nuclear reactors on submarines in the 1950's. These large systems used eutectic alloy of sodium and potassium (also known as NaK) and in some cases, eutectic alloys of lead and bismuth. A large number of patents have been awarded in connection with these large-scale systems.

One advantage of liquid metal coolants is that they can be readily pumped by the magneto-hydrodynamic (MHD) effect. In particular, MHD pumps do not have any moving components, which greatly simplifies their construction and improves their reliability.

In addition, MHD pumps can be made very compact and lightweight. Liquid metal cooling for small commercial applications (e.g., electronics) is deemed to have been enabled by the discovery of a low melting point (−19° C.) eutectic alloy of gallium, indium, and tin, which is known as galinstan (see, for example, U.S. Pat. No. 5,800,060). Galinstan is non-toxic, stable in air, and it readily wets many materials. Other room-temperature-melting alloys of gallium have been reported. This opportunity was recognized in several recent disclosures, for example, U.S. Pat. Nos. 7,505,272, 7,697,291, 7,539,016, 7,764,499, 7,701,716, 7,672,129, 7,245,495, 7,861,769, and 7,131,286. No devices based on these disclosures are known to be currently on the market.

The above disclosures typically suggest a traditional layout for a thermal management system found already in the above mentioned nuclear systems: a heat exchanger (HEX) for receiving heat, HEX for rejecting heat, plumbing, and a pump. Such configurations may not self-contained and may be impractical for many applications because they may have a large size, are complex, have many seals, and are costly to produce. In addition, above disclosures do not address the challenges of handling and pumping liquid metal, namely:
1) Galinstan has a specific gravity of about 6.4, which means that galinstan flow loop may require nearly 7-times more pumping power to operate than a comparable water flow loop having the same flow velocity.
2) Gallium alloys have a tendency to form amalgams with other metals, which may result in severe corrosion in commonly used engineering metals. In addition, the solid inter-metallic compounds produced by the corrosive action may form deposits inside the liquid metal flow channel, impeding the heat transfer, and possibly block the flow channels.
3) Pumping of liquid metal with an electromagnetic pump may be very simple in theory, but it may be challenging in practice due to possible complex magneto-hydro-dynamic (MHD) boundary layers and MHD instabilities.
4) Volumetric specific heat of liquid metal may be only about half of that of water. Hence, a liquid metal cooling loop may require higher flow throughput to carry away the same amount of heat as a comparable water loop having the same temperature rise in the coolant.

The above indicates that for a superior performance, a liquid metal cooling hardware may not have an arbitrary configuration and/or arbitrary operating parameters.

In summary, prior art does not teach a thermal management device capable of removing heat at very loads and high fluxes that is also compact, lightweight, self-contained, capable of accurate temperature control, has a low thermal resistance, is easy to fabricate, is robust to corrosion by liquid metal, and requires very little power to operate. It is against this background that the significant improvements and advancements of the present invention have taken place.

### SUMMARY OF THE INVENTION

The present invention provides a thermal management device (TMD) suitable for interfacing a heat generating component (HGC), which requires removal of waste heat at high-flux to a heat sink, which may have only low-heat flux capability. The TMD of the present invention is a self-contained device with an internal flow loop flowing liquid metal coolant, which is pumped by an MHD pump. The TMD of the present invention may be used to cool HGC requiring removal of waste heat at very high heat flux. In particular, the TMD removes waste heat at high flux from an HGC and transfers it to a heat sink or environment at a reduced heat flux. For example, TMD may transfer acquired heat to a structure, heat pipe, secondary liquid coolant, phase change material (PCM), gaseous coolant, or ambient air. The TMD of the present invention may be used to cool solid-state electronic chips, semiconductor laser diodes, light emitting diodes for solid-state lighting, solid-state laser components, laser crystals, optical components, vacuum electronic components, and photovoltaic cells.

In one preferred embodiment of the present invention, the TMD comprises a body having a first surface, a second surface, a closed flow channel, and an MHD pump. The first surface is adapted for receiving heat from an HGC and the second surface is adapted for transferring (rejecting) heat to a heat sink. The flow channel forms a closed flow loop with two branches. Each of the flow loop branches is arranged to pass in the proximity of the first surface and in the proximity of the second surface. The flow channel is filled with a suitable liquid metal, which is flowed by the MHD pump. The flow loop is arranged to form impinging flow on a thin member separating the first surface from the flow channel. Heat transfer in the impinging flow is very high, which allows for removal of heat from HGC at high flux. Heat acquired by the liquid metal flow is carried by the flow and eventually transferred to an interface member separating the second surface and the flow channel. Heat is then rejected through the second surface from the TMD to a suitable heat sink or the environment.

Accordingly, it is an object of the present invention to provide a thermal management device (TMD) for removing waste heat from HGC. The TMD of the present invention is simple, compact, lightweight, self-contained, easy to fabricate, can be made of materials with a coefficient of thermal expansion (CTE) matched to that of the HGC, requires relatively little power to operate, and it is suitable for large volume production.

It is another object of the invention to provide means for cooling HGC.

It is still another object of the invention to provide means for temperature control of HGC.

It is yet another object of the invention to cool a semiconductor electronic components.

It is yet further object of the invention to cool semiconductor laser diodes.

It is a further object of the invention to cool LED for solid-state lighting.

It is still further object of the invention to cool computer chips.

It is an additional object of the invention to cool photovoltaic cells.

These and other objects of the present invention will become apparent upon a reading of the following specification and claims.

### BRIEF DESCRIPTION OF THE DRAWINGS

FIG. 1 is an isometric view of the TMD in accordance with one preferred embodiment of the present invention.

FIG. 2 cross-sectional view 2-2 of the TMD of FIG. 1.

FIG. 3 is a cross-sectional view 3-3 of the TMD of FIG. 1.

FIG. 4 is a cross-sectional view 4-4 of the TMD of FIG. 1.

FIG. 5 is an isometric view of the TMD body including a partial cross-section to expose the small opening.

FIG. 6 shows an enlarged cross-sectional view of a portion 6 of FIG. 2.

FIG. 7 is an isometric view of the MHD pump assembly.

FIG. 8 is a cross-sectional view 8-8 of the MHD pump assembly of FIG. 7.

FIG. 9 is a cross-sectional view 9-9 of the MHD pump assembly of FIG. 7.

FIG. 10 is an isometric view of the magnet core assembly.

FIG. 11 is an isometric view of the magnet core assembly of FIG. 10 flipped over.

FIG. 12 is cross-sectional view 12-12 of the magnet core assembly of FIG. 10.

FIG. 13 is cross-sectional view 13-13 of the magnet core assembly of FIG. 10.

FIG. 14 is an isometric view of the fill plug.

FIG. 15 is an isometric view of a prismatic flow separator.

FIG. 16 is an isometric view of a conical flow separator.

### DETAILED DESCRIPTION OF THE PREFERRED EMBODIMENTS

Selected embodiments of the present invention will now be explained with reference to drawings. In the drawings, identical components are provided with identical reference symbols in one or more of the figures. It will be apparent to those skilled in the art from this disclosure that the following descriptions of the embodiments of the present invention are merely exemplary in nature and are in no way intended to limit the invention, its application, or uses.

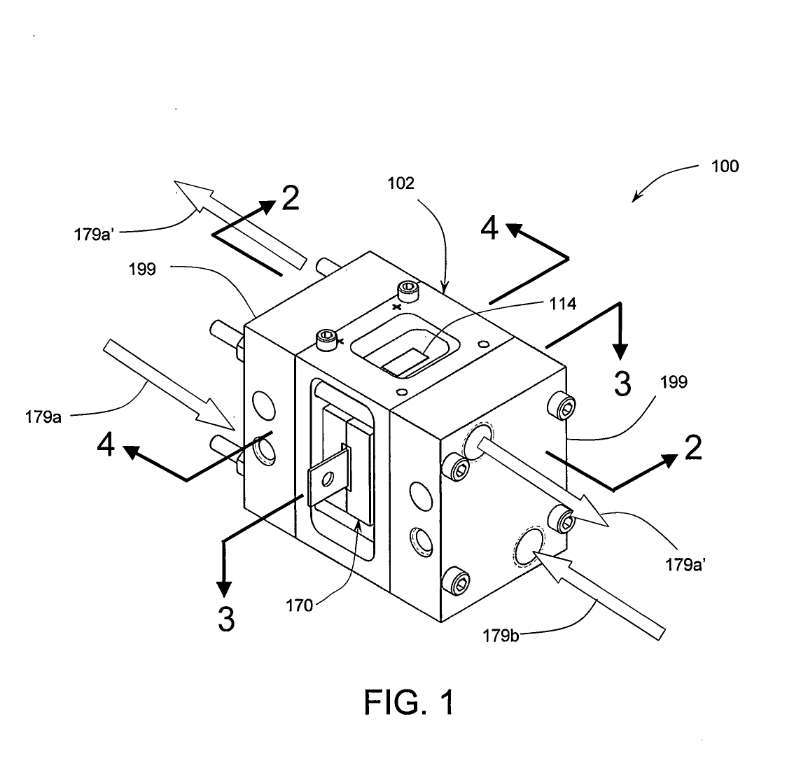

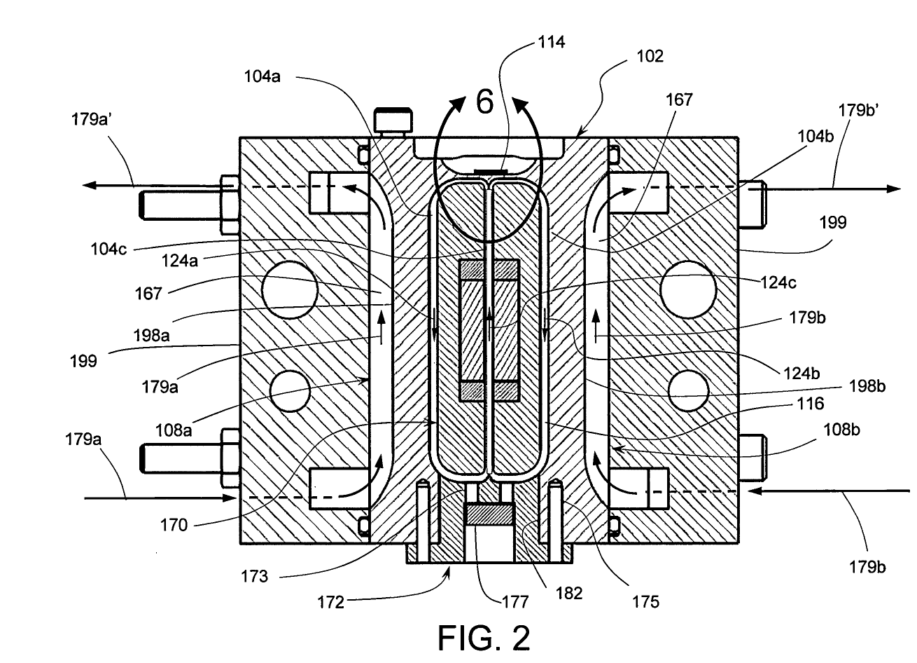

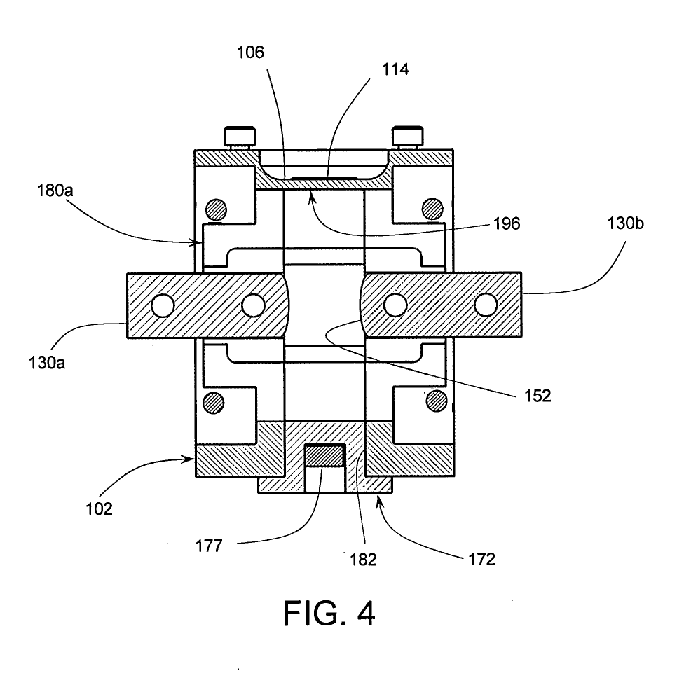

Referring now to FIG. 1, there is shown a thermal management device (TMD) 100 in accordance with one preferred embodiment of the present invention generally comprising a body 102, MHD pump assembly 170, and manifolds 199. FIGS. 2, 3, and 4 show principal cross-sectional views of the TMD 100 exposing additional elements including the fill plug 172 (FIGS. 2 and 4). As seen in FIG. 2, the body 102 together with the MHD pump assembly 170 and with the fill plug 172 in an assembled condition form an internal cavity defined as a flow channel comprising flow channel portions 104a, 104b, and 104c. The flow channel is substantially filled with liquid metal coolant 116.

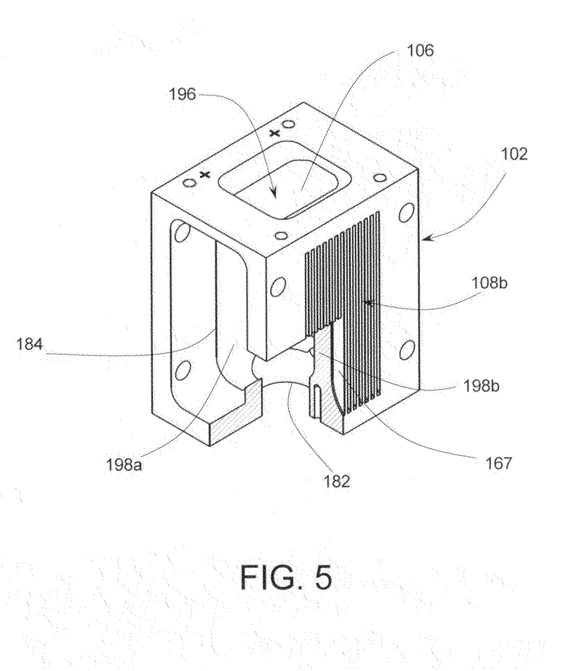

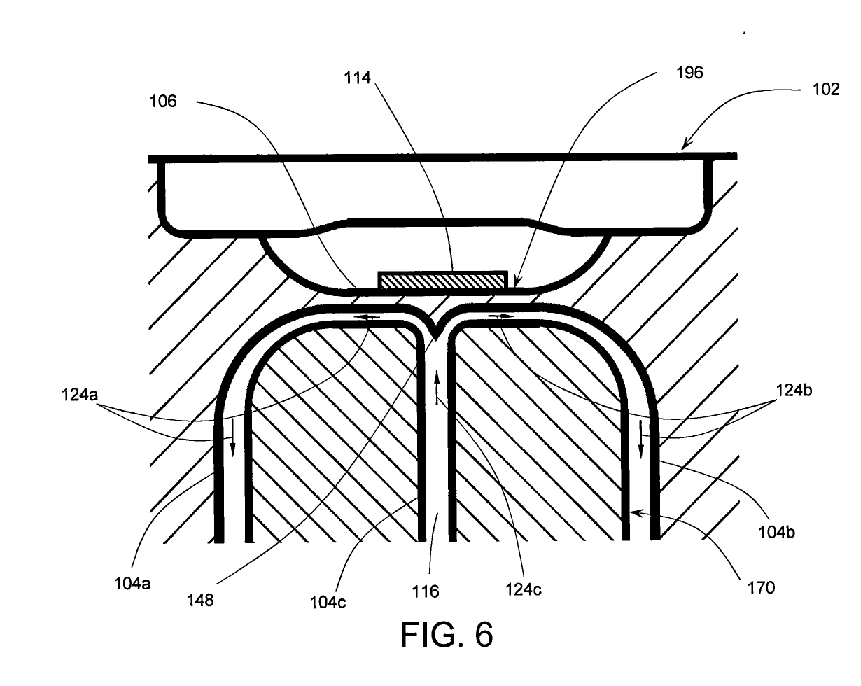

The body 102 (shown as a stand alone component in FIG. 5) further comprises a large opening 184, a small opening 182, a thin member 196, interface members 198a and 198b, and a flow separator 148 (FIG. 6). The large opening 184 of the body 102 is suitable for precision fitting of the MHD pump assembly 170. Referring now again to FIG. 2, the small opening 182 of the body 102 is suitable for receiving the fill plug 172. In addition, the body 102 comprises a heat receiving surface 106 (FIG. 6) forming the exterior surface of the thin member 196. Furthermore, the body 102 comprises heat rejection surfaces 108a and 108b forming the exterior surfaces of the respective interface members 198a and 198b. The heat receiving surface 106 is adapted for receiving heat from a heat generating component (HGC), and the heat rejection surfaces 108a and 108b are adapted for rejecting heat to a heat sink or environment. In particular, the heat rejection surfaces 108a and 108b are formed into a multitude of channels 167 (FIGS. 2, 3, and 5) suitable for flowing a secondary coolant. As seen in FIG. 2, the channels 167 fluidly couple to internal distribution channels inside the manifolds 199 to facilitate supply and drainage of secondary coolant.

The body 102 may be formed as a monolithic structure or as an assembly made from discrete components. In either case, the thin member 196 and the interface members 198a and 198b of the body 102 are each preferably made of material having very high thermal conductivity. Suitable materials for construction of the thin member 196 and the interface members 198a and 198b of may include copper, copper tungsten alloy, tungsten, molybdenum, aluminum, silicon, berylia, silicon carbide, and aluminum nitride. The thin member 196 and the interface members 198a and 198b do not have to be made from the same materials. Thin member 196 is preferably made between 0.25 and 1.00-milimeter thick to facilitate efficient flow of heat therethrough while maintaining structural integrity. Referring now to FIG. 6, the thin member 196 may include a flow separator 148 positioned to be in the center of the flow channel portion 104c. The surface of the thin member 196 facing the flow channel may also include ridges or extensions to increase the contact area with the liquid metal coolant 116.

A heat generating component (HGC) 114 (FIGS. 1, 2, 4, and 6) may be also attached to the heat receiving surface 106 of the body 102 and arranged to be in a good thermal communication therewith. Preferably, the HGC 114 is centered on the flow separator 148 (FIG. 6). The HGC 114 may be, but it is not limited to a solid-state electronic chip, semiconductor laser diode, light emitting diodes (LED), solid-state laser crystal, optical component, x-ray tube anode, or a photovoltaic cell. If desired, the thin member 196 of the body 102 may be made from material having a coefficient of thermal expansion (CTE) matched to the CTE of the HGC 114. The HGC 114 may be attached and thermally coupled to the first surface 106 with a suitable joining material having acceptably good thermal conductivity. Suitable joining materials may include solder, epoxy, and adhesive. Alternatively, HGC 114 may be diffusion bonded onto surface 106. As another alternative, the HGC 114 may be maintained in a mechanical contact with the heat receiving surface 106 and suitable enhancement to thermal contact therebetween may be provided by thermally conductive paste or fusible alloy or liquid metal. If desired, a suitable electrical insulating member having high thermal conductivity (not shown) may be installed between the HGC 114 and the surface 106. Such an electrical insulating member may be fabricated from aluminum nitrate, berylia, or alike.

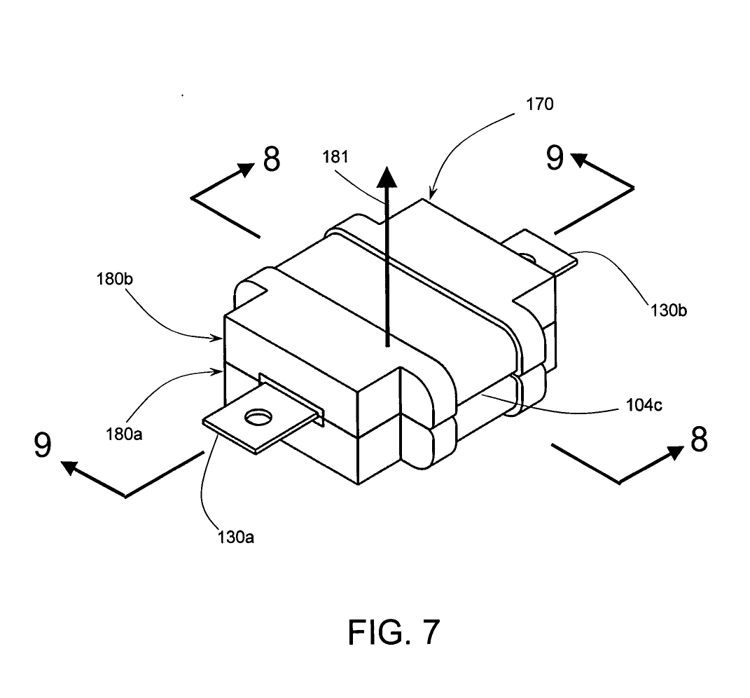

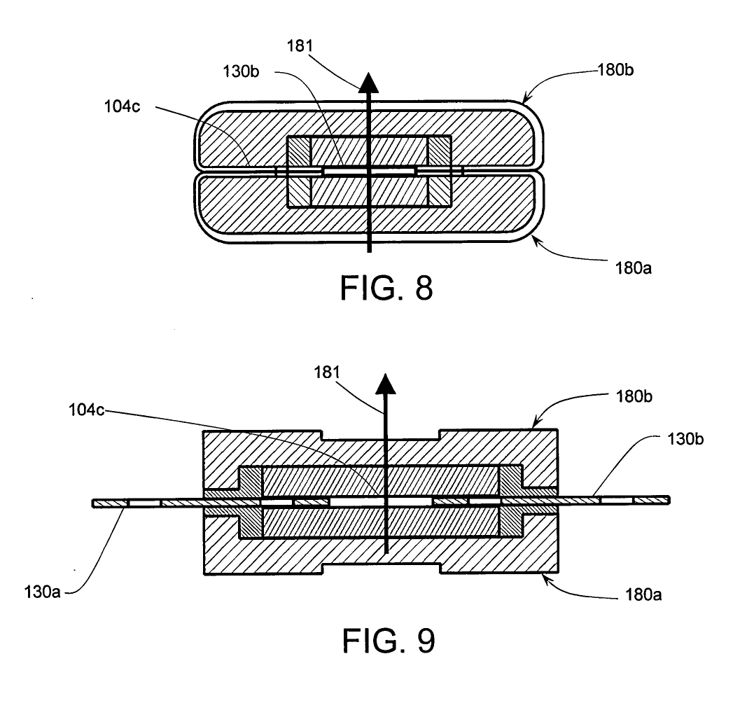

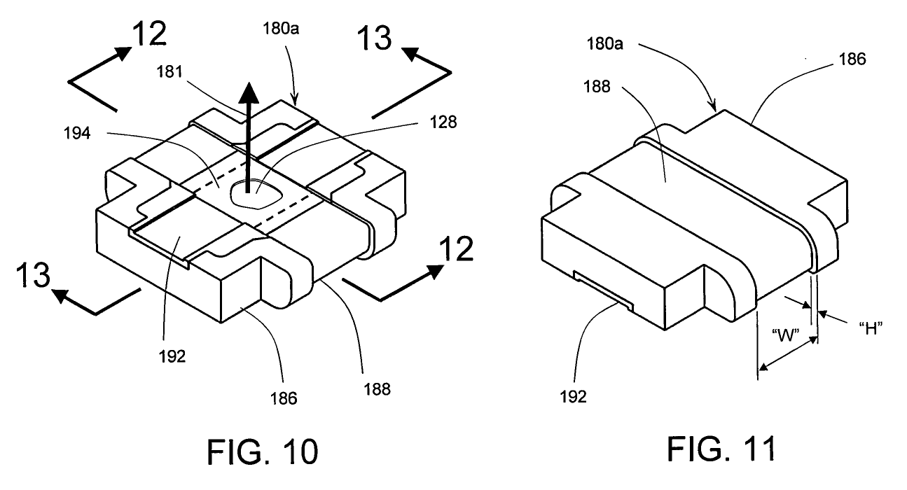

Referring now to FIG. 7, there is shown an isometric view of the MHD pump assembly 170 comprising two magnet core assemblies 180a and 180b and electrodes 130a and 130b. The two magnet core assemblies 180a and 180b are relatively positioned as shown in FIG. 7 to form the flow channel portion 104c (see also FIGS. 8 and 9). The two magnet core assemblies 180a and 180b are of identical structural construction except that the orientation of the magnetization vector of magnets 128 (FIG. 10) is arranged so that when the magnet core assemblies are configured into the MHD pump assembly 170 as shown in FIG. 7, the magnetization vectors are aligned with the arrow 181. Another words, the magnetization vectors of the magnets 128 in magnet core assemblies 180a and 180b should be arranged so that their magnetization vectors are substantially pointing in the same direction when the MHD pump assembly 170 (FIG. 7) is formed. Because of the magnetization vector alignment, two magnet core assemblies 180a and 180b attract each other. As a result, the MHD pump assembly 170 may be formed without any fasteners, thus allowing for simple construction and assembly.

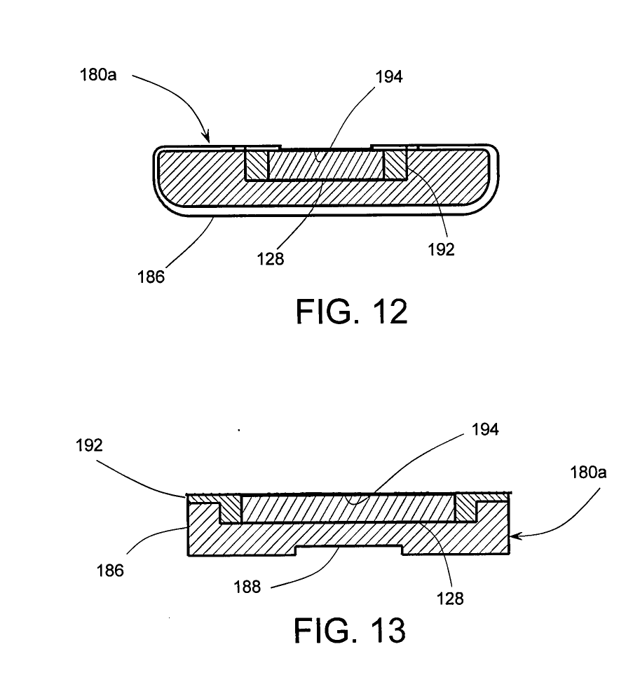

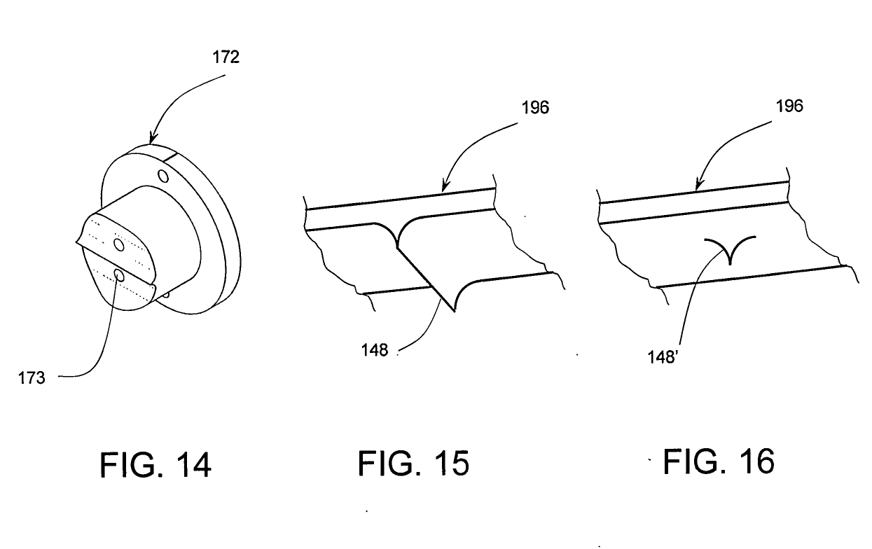

Isometric views of the magnet core assembly 180a are shown in FIGS. 10 and 11. FIG. 12 is a cross-sectional view 12-12 of the magnet core assembly of FIG. 10 showing a core structure 186 equipped with a magnet 128, electrically insulating filler material 192, and an electrically insulating film 194. The core structure 186 is formed from a suitable ferromagnetic material capable of carrying magnetic flux at high density such as iron, steel, low carbon steel, core iron (e.g., Consumet® by Cartpenter Steel), pure iron, nickel-iron alloys such as Hiperco®, or alike. The electrically insulating filler material 192 may be epoxy, or plastic (e.g., Ultem), ceramic, or other suitable material having good electrical insulating properties. The core structure 186 has a grove 188 designed to form a portion of the flow channel when the MHD pump assembly 170 is formed and installed into the body 102. The grove 188 is substantially circumferential having a width “W” and a height “H”. Preferably, the width “W” is much larger than the height “H”. For example, the width “W” may have a dimension in the range of 3 millimeters to 20 millimeters and the height “H” may have a dimension in the range of 0.1 millimeters to 2 millimeters. The width W″ and the height “H” may not have to be constant around circumference of the structure 186.

The electrically insulating film 194 may be a suitable firm formed from plastic (e.g., Mylar® or Kapton®), epoxy, or other material having good electrical insulating properties. The electrically insulating filler material 192, and the electrically insulating film 198 are applied in a suitable manner that prevents electrical contact between each of the electrodes 130a and 130b and each the core structure 186, between each of the electrodes 130a and 130b and the magnets 128 of either magnet core assembly 180a and 180b.

The magnet 128 (FIGS. 10, 12, and 13) is a suitable permanent magnet magnetized through its large faces in a direction parallel to the arrow 181. The magnet 128 is preferably a rare earth permanent magnet formed from samarium-cobalt (SmCo) or from neodymium-iron-boron (NdFeB) materials.

The electrodes 130a and 130b are preferably made of tungsten, tantalum, or other suitable material having high electrical conductivity as well as robustness to erosion by electrical arc. Alternatively, the electrode may be made of copper or copper alloy and it may be plated with a suitable refractory metal such as, but not limited to molybdenum, tungsten, tantalum, ruthenium, osmium, and iridium. The edge 152 of the electrodes facing the flow channel 104c may be curved (as shown in FIG. 4) or it may be straight. Curved edge is deemed to make the electrode less susceptible to electrical arcing.

The body 102 and the MHD pump assembly 170 are arranged so that during installation, the MHD pump assembly 170 slides precisely into the large opening 184 of the body 102. Once the MHD pump assembly 170 is installed into the body 102, a suitable adhesive or sealant (e.g., epoxy) may be applied along the joints to hold the MHD pump assembly 170 in the body 102 and to seal the flow channel to prevent potential leakage of the liquid metal 116 from within. Adhesive or sealant may be also applied along the joints between magnet core assemblies 180a and 180b, and near the electrodes.

With the MHD pump assembly 170 installed into the body 102, a flow channel is formed generally by the gap between the MHD pump assembly 170 and the body 102. The flow channel forms a closed flow loop having a general shape of figure “8” having a main flow channel common 104c and two branches, one formed by the branch flow channel portion 104a and the other by the branch flow channel portion 104b. The flow channel portions 104a, 104b, and 104c contain a suitable liquid metal coolant 116. Preferably, the flow channel is not entirely filled with the liquid metal and at least some small void space free of liquid metal is provided inside the flow channel to allow for thermal expansion (and/or phase change expansion) of the liquid metal coolant. Such void space may be filled with suitable elastomeric material.

Preferably, the liquid metal coolant 116 has a good thermal conductivity, low viscosity, and low freezing point. For the purposes of this disclosure, the term “liquid metal” shall mean suitable metals (and their suitable alloys) that are in a liquid (molten) state at their operating temperature. Examples of suitable liquid metals include nontoxic room temperature melting alloys comprising of gallium, indium, and tin (GaInSn). Ordinary or eutectic liquid metal alloys may be used. Examples of suitable gallium-based liquid eutectic metal alloys include Indalloy 51 and Indalloy 60 (manufactured by Indium Corporation in Utica, N.Y.), galinstan (obtainable from Geratherm Medical AG in Geschwenda, Germany). In particular, galinstan is an eutectic alloy reported to contain 68.5% by weight of gallium, 21.5% by weight of indium and 10% by weight of tin, and having a melting point around minus 19 degrees Centigrade. Examples of suitable gallium-based liquid metal alloys may be also found in the U.S. Pat. No. 5,800,060 issued to G. Speckbrock et al., on Sep. 1, 1998. A new class of liquid metal alloys recently disclosed by Brandeburg et al. in the U.S. Pat. No. 7,726,972 and having reportedly extended useful temperature range down to minus 36 degrees Centigrade may be also usable with the subject invention. The Brandeburg's alloy differs from the commercially available GaInSn alloy in that it additionally includes 2%-10% of zinc (Zn).

It is important that all surfaces of TMD 100 that may come into contact with the liquid metal coolant 116 be made of compatible materials. In particular, it is well know that liquid gallium and its alloys severely corrode many metals. Literature indicates that certain refractory metals such as tantalum, tungsten, and ruthenium may be stable in gallium and its alloys. See, for example, “Effects of Gallium on Materials at Elevated Temperatures,” by W. D. Wilkinson, Argonne National Laboratory Report ANL-5027, published by the U.S. Atomic Energy Commission (August 1953). To protect against corrosion, vulnerable surfaces that may come into contact with the liquid metal coolant (for example portions of the body 102) may be coated with suitable protective film. Suitable protective coatings and films for copper parts (e.g., the body 102) may include sulfamate (electroless) nickel, electroplated ruthenium, titanium nitride (TiN), and diamond-like coating (DLC). Diamond-like coating may be obtained from Richter Precision in East Petersburg, Pa. The Applicant has determined that core structure 186 made of substantially pure iron or core iron (e.g., Consumet® by Cartpenter Steel) may not require a protective coating. Reduced need for protective coatings simplifies fabrication and reduces cost.

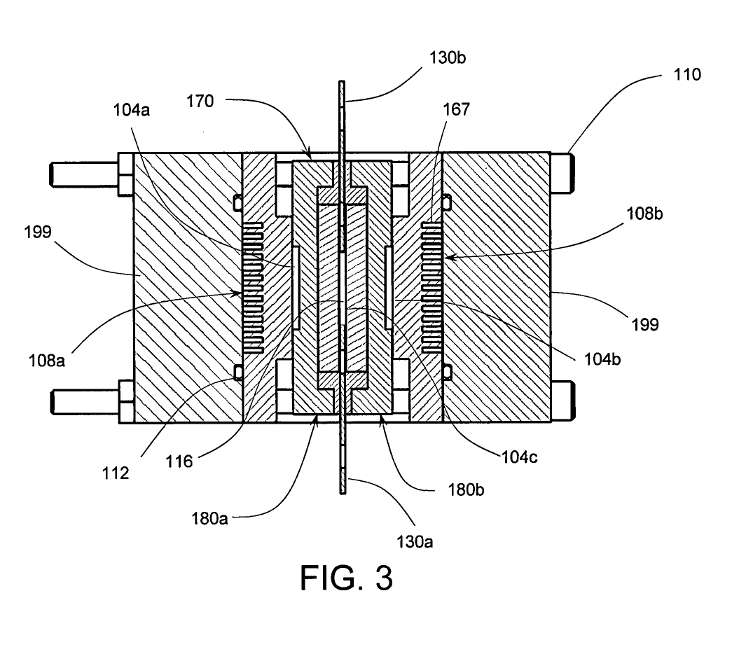

Referring now again to FIG. 2, the TMD 100 may be filled with liquid metal coolant 116 by removing the fill plug 172 and orienting the small opening 182 of the body 102 in upward direction. Liquid metal coolant may be poured into the small opening 182. When the fill is complete, the fill plug 172 may be pushed into the small opening 182 to close it. Proper orientation of the fill plug 172 with respect to the body 102 is ensured with alignment pins 175. Any excess liquid metal coolant may be released through the vent ports 173. After removing the excess liquid metal coolant from the vent port, the vent port 173 may be sealed using a suitable sealant 177. Secondary coolant manifolds 199 may be attached with bolts 110 and sealed with o-rings 112 (FIG. 3).

In operation, direct current electric potential is applied to the electrodes 130a and 130b of the TMD 100 (FIG. 1). The liquid metal coolant 116 inside the flow channel portion 104c makes an electrical contact with the electrodes (FIG. 3) and allows an electric current to flow through the liquid metal coolant from one electrode to electrode. The direction of the electric current (as defined by the polarity of the electric current source) drawn though the liquid metal coolant is coordinated with the direction of the magnetic field generated by the magnets 128 in the MHD pump assembly 170, so that the resulting magneto-hydrodynamic (MHD) effect causes the liquid metal coolant 116 to flow inside the main flow channel portion 104c in the direction indicated by the arrow 124c in FIG. 2. Referring now to FIG. 6, a stream of liquid metal coolant identified by the arrow 124c impinges onto the flow separator 148. The flow separator 148 has a sharp edge. As a result, the liquid metal coolant stream identified by the arrow 124c becomes separated (split) into two streams respectively identified by the arrows 124a and 124b. The two streams respectively identified by the arrows 124a and 124b are about the same size. Heat transfer from the thin member 196 to the liquid metal coolant is greatly enhanced because of the sharp changes in the direction of liquid metal coolant flow in the vicinity of the flow separator 148. Referring now again to FIG. 2, the liquid metal coolant stream identified by the arrow 124a flows through the branch flow channel portion 104a toward the fill plug 172. The liquid metal coolant stream identified by the arrow 124b flows through the branch flow channel portion 104b toward the fill plug 172. In vicinity of the fill plug 172 the liquid metal coolant stream identified by the arrow 124a and the liquid metal coolant stream identified by the arrow 124b are combined and fed into the flow channel portion 104c in the MHD pump assembly 170. As a result, liquid metal coolant completes a round trip through the closed flow loop.

Concurrently, secondary coolant streams 179a and 179b of fresh secondary coolant are injected into the manifolds 199 as shown in FIG. 1. Suitable secondary coolant may be a liquid (such as water, ethylene glycol, alcohol, or Freon®) or gas such as air. The HGC 114 is installed onto the thin member 196 and operated. Waste heat from the HGC 114 is transferred through the heat receiving surface 106 into the thin member 196 of the body 102 (FIG. 6). The liquid metal coolant streams identified by the arrows 124a and 124b sweep by the thin member 196, receive the waste heat from the thin member 196, and carry the waste heat to the interface members 198a and 198b respectively. The waste heat is then transferred from the liquid metal coolant to the interface members 198a and 198b, conducted through them, and respectively transferred to the secondary coolant streams 179a and 179b flowing through the channels 167 (FIG. 2). Expended (warmer) secondary coolant exits the manifolds 199 as secondary coolant streams 179a′ and 179b′. Note that the heat flux in the interface members 198a and 198b can be much lower than in the thin member 196.

Temperature of the HGC 114 may be controlled by controlling the flow velocity of the coolant 116 inside the closed flow loop. This can be accomplished by controlling the current drawn through the coolant 116 via electrodes 130a and 130b. For example, by drawing more current through the coolant 116, the coolant flow velocity may be increased, and the HGC waste heat may be removed at a lower temperature differential between the HGC and the secondary coolant streams 179a and 179b. Conversely, by drawing less current through the liquid metal coolant 116, the liquid metal coolant velocity may be decreased, and the HGC waste heat may be removed at a higher temperature differential between the HGC and the secondary coolant streams 179a and 179b. Thus, by drawing more current through the coolant 116, the temperature of the HGC 114 may decreased, and by drawing less current through the coolant 116, the temperature of the HGC 114 may be increased. An automatic closed-loop temperature control of the HGC 114 can be realized by sensing HGC temperature (for example, with a thermocouple or infrared sensor) and using this information to appropriately control the current drawn through the coolant 116. In particular, if the HGC 114 is an LED, its temperature may be inferred from the output light spectrum. A means for sensing the LED light spectrum may be provided for this purpose. If the HGC 114 is a semiconductor laser diode, its temperature may be inferred from the output light center wavelength. A means for sensing the semiconductor laser diode output light center wavelength may be provided for this purpose. If the HGC 114 has electric currents flowing therethrough, HGC temperature may be determined from certain current and/or voltages supplied to or flowing through in the HGC. If the coolant used in the TMD 100 is susceptible to freezing (solidifying) due to ambient conditions during inactivity, the TMD may be equipped with an electric heater to warm the coolant up to at least its melting point. Alternatively, the HGC 114 may be operated to warm up the TMD.

The invention may be also practiced with alternative heat rejection surfaces 180a and 108b. For example, the heat rejection surfaces 180a and 108b may be formed for interfacing a solid heat sink, a heat pipe, a radiation panel, or a structure. The invention may be also practiced with flow separators of various shapes. For example, FIG. 15 shows a flow separator 148 having a general prismatic shape. As another example, FIG. 16 shows a flow separator 148 having a general conical shape.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” and “includes” and/or “including” when used in this specification, specify the presence of stated features, integers, steps, operations, elements, and/or components, but do not preclude the presence or addition of one or more other features, integers, steps, operations, elements, components, and/or groups thereof.

The terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

The term “suitable,” as used herein, means having characteristics that are sufficient to produce a desired result. Suitability for the intended purpose can be determined by one of ordinary skill in the art using only routine experimentation.

Moreover, terms that are expressed as “means-plus function” in the claims should include any structure that can be utilized to carry out the function of that part of the present invention. In addition, the term “configured” as used herein to describe a component, section or part of a device includes hardware and/or software that is constructed and/or programmed to carry out the desired function.

Different aspects of the invention may be combined in any suitable way.

While only selected embodiments have been chosen to illustrate the present invention, it will be apparent to those skilled in the art from this disclosure that various changes and modifications can be made herein without departing from the scope of the present invention as defined in the appended claims. Furthermore, the foregoing description of the embodiments according to the present invention are provided for illustration only, and not for the purpose of limiting the present invention as defined by the appended claims and their equivalents. Thus, the scope of the present invention is not limited to the disclosed embodiments.

What is claimed is:

1. A thermal management device (TMD) comprising: a body, a flow channel, a magnetohydrodynamic (MHD) pump, and liquid metal coolant;
a) said body comprising a thin member adapted for receiving heat from a heat generating component (HGC);
b) said flow channel being formed as a closed flow loop comprising a main flow channel portion and two branch flow channel portions;
c) said flow loop being substantially filled with said liquid metal coolant;
d) said MHD pump being installed within said body;
e) said MHD pump being arranged to flow said liquid metal coolant around said flow loop; and
f) said liquid metal coolant being arranged to form a flow stream impinging onto said thin member.

2. The thermal management device of claim 1, wherein said main flow channel portion passes through said MHD pump; and each of said two branch flow channel portions connects the discharge port of said MHD pump to the suction port of said MHD pump.

3. The thermal management device of claim 1, further comprising grooves and interface members; said grooves being integral to said MHD pump and said interface members integral to said body; said grooves forming segments of said two branch flow channel portions; said interface members each comprising a surface for rejecting heat; and said grooves being arranged to flow said liquid metal coolant to sweep over portions of said interface members.

4. The thermal management device of claim 1, further including a flow separator formed on said thin member; said flow separator being arranged to receive said flow stream impinging onto said thin member.

5. The thermal management device of claim 4, wherein said flow separator is arranged to divide said flow stream impinging onto said thin member into two steams; one of said two streams being fed into one of said two branch flow channel portions; and another of said two streams being fed into another of said two branch flow channel portions.

6. The thermal management device of claim 1, wherein said flow stream impinging onto said thin member is arranged to form inside said main flow channel portion.

7. The thermal management device of claim 1, wherein said flow channel is being formed by portions of said body and portions of said MHD pump.

8. A thermal management device comprising: a body, a flow channel, a magnetohydrodynamic (MHD) pump, and liquid metal coolant;
a) said body comprising a thin member adapted for mounting a heat generating component;
b) said flow channel forming a closed flow loop comprising a main flow channel portion and two branch flow channel portions;
c) said thin member comprising a flow separator centered on said main flow channel portion;
d) said flow channel being substantially filled with said liquid metal coolant;
e) said MHD pump being installed within said body;
f) said MHD pump substantially forming said main flow channel portion;
g) said MHD pump being arranged to flow said liquid metal coolant around said flow loop;
h) said MHD pump being arranged to generate a discharge flow stream;
i) said discharge flow stream being arranged to impinge onto said flow separator; and
j) said flow separator being arranged to divide said discharge flow stream into two flow steams of substantially equal size.

9. The thermal management device of claim 8, further comprising grooves and interface members; said grooves being integral to said MHD pump and said interface members integral to said body; said grooves being arranged to flow said liquid metal coolant to wash over portions of said interface members.

10. The thermal management device of claim 9, wherein said grooves are arranged to flow said two flow streams from the discharge port of said MHD pump to the suction port of said MHD pump.

11. The thermal management device of claim 8, wherein said main flow channel portion is substantially perpendicular to said thin member.

12. The thermal management device of claim 8, further comprising a heat generating component (HGC) mounted on said thin member; said HGC being selected from the family of a solid-state electronic chip, semiconductor laser diode, light emitting diodes (LED), solid-state laser crystal, optical component, x-ray tube anode, and a photovoltaic cell.

13. The thermal management device of claim 8, further comprising an interface member adjacent to said branch flow channel portion; said interface member being adapted to receiving heat from said liquid metal coolant; and said interface member being cooled by external means.

14. The thermal management device of claim 8, further comprising a large opening in said body; said MHD pump being fabricated to precisely fit into said large opening; and said MHD pump being installed into said body by sliding it into said large opening.

15. The thermal management device of claim 8, wherein said MHD pump is formed by two structurally identical magnet core assemblies and two electrodes; said magnet core assemblies each being formed by a core structure, a permanent magnet, and electrical insulating materials.

16. The thermal management device of claim 8, further comprising a fill plug having two sealable vent ports and an alignment pin.

17. The thermal management device of claim 8, wherein said flow separator has a shape selected from generally prismatic shape and generally conical shape.

18. A method for thermal management of a heat generating component comprising the steps of:
a) providing a body, a flow channel, a magnetohydrodynamic (MHD) pump, and liquid metal coolant; said body comprising a thin member and at least one interface member; said flow channel forming a closed flow loop comprising a main flow channel portion and two branch flow channel portions; said thin member comprising a flow separator centered on said main flow channel portion; said flow loop being substantially filled with said liquid metal coolant;
b) delivering heat to said thin member;
c) operating said MHD pump to flow said liquid metal coolant around said flow loop;
d) forming a stream of liquid metal coolant;
e) directing said stream of liquid metal coolant to impinge onto said flow separator;
f) transferring heat from said thin member into said stream of liquid metal coolant;
g) dividing said stream of liquid metal coolant directed to impinge onto said flow separator into two separate streams of liquid metal coolant of about same size;
h) flowing said separate streams of liquid metal coolant to sweep over portions of said interface members;
i) transferring heat from said separate streams of liquid metal coolant to said interface members;
j) transferring heat from said interface members to one of liquid coolant, gaseous coolant, heat pipe, radiation panel, phase change material, and structure.

19. The method for transferring heat of claim 15, wherein said MHD pump forms at least a portion of said main flow channel.

20. The method for transferring heat of claim 15, further including a comprising a heat generating component (HGC) attached to said thin member; said HGC being selected from the family of a solid-state electronic chip, semiconductor laser diode, light emitting diodes (LED), solid-state laser crystal, optical component, x-ray tube anode, and a photovoltaic cell.
